(19) United States
(12) Patent Application Publication
(10) Pub. No.: US 2016/0108254 A1
(43) Pub. Date: Apr. 21, 2016

(54) ZINC IMMERSION COATING SOLUTIONS, DOUBLE-ZINCATE METHOD, METHOD OF FORMING A METAL PLATING FILM, AND SEMICONDUCTOR DEVICE

(71) Applicant: MELTEX INC., Tokyo (JP)

(72) Inventors: Yuichi KOYAMA, Asaka-shi (JP); Tatsuya GODA, Ageo-shi (JP); Mariko HAYASHI, Tokyo (JP)

(21) Appl. No.: 14/517,055

(22) Filed: Oct. 17, 2014

(51) Int. Cl. C09D 5/24; C23C 18/16; H01L 23/532; H01L 21/768; H01L 21/288; C23C 18/31; C23C 18/18

(52) U.S. Cl. CPC C09D 5/24; C23C 18/31; C23C 18/165; C23C 18/1827; H01L 21/7685; H01L 21/288; H01L 23/53223

(57) ABSTRACT

Invention provides a zinc immersion coating solution used in the double-zincate method for applying first and second zinc immersion coating treatments to aluminum or aluminum alloy. Zinc immersion coating solution used for first zinc immersion coating treatment at least contains a zinc compound, alkali hydroxide, iron salt, chelating agent for complexation of iron ions, and zinc immersion coating inhibitor that is at least one out of the group consisting of a polymer of a secondary amine, polymer of a tertiary amine, and polymer of a quaternary amine, or copolymer containing the same, and zinc immersion coating solution used for second zinc immersion coating treatment at least contains a zinc compound, alkali hydroxide, iron salt, chelating agent for complexation of iron ions, and zinc immersion coating inhibitor that is at least one out of the group consisting of a primary and secondary amines, and a tertiary amine.

### BACKGROUND OF THE INVENTION

1. Field of the Invention

The present invention relates to a double-zincate method that is a pretreatment for plating on aluminum or an aluminum alloy, zinc immersion coating solutions used with the double-zincate method, a method of forming a metal plating film on a material that is aluminum or an aluminum alloy, and a semiconductor device having an aluminum or aluminum alloy electrode.

2. Description of the Prior Art

There has so far been aluminum used for metal interconnecting wiring of semiconductor devices in view of electric conductivity, heat resistance, cost, chemical stability, reactivity relative to silicon and silicon oxide materials, and adhesiveness, etc. By nature, aluminum is likely to migrate in a silicon or silicon oxide material during the passage of electric currents by way of an electromigration phenomenon, and to prevent this there has been some methods known such as a method of interposing a titanium material layer between aluminum and other material to create a laminated structure, and a method of using an aluminum alloy containing 0.5 to 1.0% by weight of silicon or copper in aluminum. Further, aluminum or aluminum alloys such as an aluminum-silicon alloy, an aluminum-copper alloy, and an aluminum-silicon-copper alloy have been used as a connecting electrode material of the outermost layer of a semiconductor device.

In recent years, techniques for applying electroless nickel plating, displacement gold plating or the like to such an aluminum or aluminum alloy electrode to improve solder wettability for the purpose of forming an electrode with solder paste or the like has attracted attention in the high-density mounting field (U.S. Pat. No. 4,205,099).

The process best-suited for applying electroless nickel plating to aluminum or aluminum alloys is a double-zincate method that now finds industrially wide applications for the production of hard discs or the like. Usually in the double-zincate method, degreasing and acid or alkali etching treatments are carried out, and there is then the so-called double-zincate treatment carried out in which two zinc immersion coating treatments involving first zinc immersion coating→stripping by nitric acid→second zinc immersion coating are performed to form a dense zinc immersion coating film. Thereafter, a nickel film is formed by electroless nickel plating on the zinc immersion coating film. Providing a dense zinc immersion coating film that cannot be obtained through a one-stage zinc immersion coating treatment and making sure good enough plating appearance and adhesion strength, such a double-zincate method has generally be used for the pre-plating treatment for aluminum or aluminum alloys.

Various attempts have already been made for the purpose of improving plating steps using such a double-zincate method as described above, leading to diverse proposals including zinc immersion coating methods and zinc immersion coating solutions. For instance, there is the mention of JP(A) 62-256226 disclosing an example of applying ultrasonic waves during the zincate process to allow for a smooth and uniform zinc immersion coating reaction, and JP(A)'s 6-128757 and 10-1778 disclosing that additives are added to a zinc immersion coating solution to gain control of deposition of the zinc immersion coating film. In any event, two zinc immersion coating treatments are carried out using the zinc immersion coating solutions having the same composition. It has also been proposed to use for the first zinc immersion coating treatment a zinc immersion coating solution that contains gluconic acid as a chelating agent thereby preventing pitting of the aluminum surface due to iron ions (JP(A) 2001-316831).

In the first and second zinc immersion coating treatments of the double-zincate method, a zinc immersion coating inhibitor is added to each zinc immersion coating solution to control deposition of zinc to optimize the amount of deposition of zinc. After the completion of a conventional double-zincate process, however, the effect on inhibition of zinc immersion coating remains insufficient, and a problem with a plating step after the double-zincate process is that because the zinc immersion coating inhibitor is trapped in, coating shape defects occur, resulting in a lowering of connection reliability.

The situations being like this, one object of the present invention is to provide a zinc immersion coating solution and a double-zincate method ensuring that a dense plated zinc immersion coating film can be formed on aluminum or an aluminum alloy thereby providing a plating film having good enough appearance and sufficient adhesion strength.

It is another object of the present invention to provide a metal plating method capable of forming on a material that is aluminum or aluminum alloys a metal plating film having good enough appearance and sufficient adhesion strength.

It is yet another object of the present invention to provide a semiconductor device in which an aluminum or aluminum alloy electrode includes a metal plating film having good enough appearance and sufficient adhesion strength.

### SUMMARY OF THE INVENTION

The present invention provides zinc immersion coating solutions used with a double-zincate method of applying a first zinc immersion coating treatment and a second zinc immersion coating treatment to aluminum or an aluminum alloy, wherein a zinc immersion coating solution used for the first zinc immersion coating treatment at least contains a zinc compound, an alkali hydroxide, an iron salt, a chelating agent for complexation of iron ions, and a zinc immersion coating inhibitor, said zinc immersion coating inhibitor being at least one out of the group consisting of a polymer of a secondary amine, a polymer of a tertiary amine, and a polymer of a quaternary amine, or a copolymer containing the same, and a zinc immersion coating solution used for the second zinc immersion coating treatment at least contains a zinc compound, an alkali hydroxide, an iron salt, a chelating agent for complexation of iron ions, and a zinc immersion coating inhibitor, said zinc immersion coating inhibitor being at least one out of the group consisting of a primary amine, a secondary amine, and a tertiary amine.

In one embodiment of the zinc immersion coating solution according to the invention, the aforesaid zinc immersion coating solution used for the first zinc immersion coating treatment contains the aforesaid zinc immersion coating inhibitor in an amount ranging from 0.05 to 50 g/L, and the aforesaid zinc immersion coating solution used for the second zinc immersion coating treatment contains said zinc immersion coating inhibitor in an amount ranging from 0.01 to 1 mol/L.

In another embodiment of the zinc immersion coating solution according to the invention, the chelating agent in the aforesaid zinc immersion coating solution used for the first zinc immersion coating is gluconic acid that is contained in an amount of at least 20 times as high as iron ions in molar ratio.

In yet another embodiment of the zinc immersion coating solution according to the invention, the zinc concentration is in a range of 0.01 to 0.5 mol/L.

In a further embodiment of the zinc immersion coating solution according to the invention, the alkali hydroxide concentration is in a range of 1 to 6 mol/L.

In a further embodiment of the zinc immersion coating solution according to the invention, the iron concentration is in a range of 0.1 to 10 mmol/L.

With such zinc immersion coating solutions as described above, a uniform, dense plated zinc coating film could be obtained in the pre-plating treatment of aluminum or an aluminum alloy by the double-zincate method while preventing pitting, and any adsorption of the zinc immersion coating inhibitor onto the zinc immersion coating film after the second zinc immersion coating treatment could be held back.

The present invention also provides a double-zincate method for applying a first zinc immersion coating treatment and a second zinc immersion coating treatment to a material that is aluminum or an aluminum alloy, comprising a first zinc immersion coating step of immersing said material in a zinc immersion coating solution at least containing a zinc compound, an alkali hydroxide, an iron salt, a chelating agent for complexation of iron ions, and a zinc immersion coating inhibitor, said zinc immersion coating inhibitor being at least one out of the group consisting of a polymer of a secondary amine, a polymer of a tertiary amine, and a polymer of a quaternary amine, or a copolymer containing the same, a step of immersing said material in an aqueous solution of nitric acid, and a second zinc immersion coating step of immersing said material in a zinc immersion coating solution at least containing a zinc compound, an alkali hydroxide, an iron salt, a chelating agent for complexation of iron ions, and a zinc immersion coating inhibitor, said zinc immersion coating inhibitor being at least one out of the group consisting of a primary amine, a secondary amine, and a tertiary amine.

In one embodiment of the double-zincate method according to the invention, the aforesaid zinc immersion coating solution used in the aforesaid first zinc immersion coating step contains the aforesaid zinc immersion coating inhibitor in an amount ranging from 0.05 to 50 g/L, and the aforesaid zinc immersion coating solution used in the aforesaid second zinc immersion coating step contains the aforesaid zinc immersion coating inhibitor in an amount ranging from 0.01 to 1 mol/L.

In another embodiment of the double-zincate method according to the invention, it includes, prior to the aforesaid first zinc immersion coating step, an etching step of etching the aforesaid material by an etching solution containing copper ions, and a residue removal step of removing etching residues from said material going through said etching step, using a stripping solution capable of dissolving copper.

In yet another embodiment of the double-zincate method according to the invention, the aforesaid etching solution has a copper concentration ranging from 2 to 1,000 mg/L.

In a further embodiment of the double-zincate method according to the invention, the aforesaid etching solution is either an acidic solution containing sulfuric acid and/or phosphoric acid or an alkali solution containing a complexing agent for copper and having a pH value of at least 8.

In a further embodiment of the double-zincate method according to the invention, the aforesaid stripping solution contains as an oxidizing agent for copper at least one of nitric acid, a persulfate, and hydrogen peroxide.

In a further embodiment of the double-zincate method according to the invention, the aforesaid oxidizing agent has a concentration of at least 1 g/L.

With such a double-zincate method as described above, any pitting of aluminum or an aluminum alloy could be prevented in each of the first and second zinc immersion coating treatments and a uniform, dense plated zinc coating film can be formed, and any adsorption of the zinc immersion coating inhibitor onto the zinc immersion coating film after the second zinc immersion coating treatment can be held back.

Further, the present invention provides a method of forming a metal plating film on a material that is aluminum or an aluminum alloy, comprising an etching step of etching said material by an etching solution containing copper ions, a residue removal step of removing etching residues from said material after said etching step, using a stripping solution capable of dissolving copper, a first zinc immersion coating step of immersing said material in a zinc immersion coating solution containing a zinc compound, an alkali hydroxide, an iron salt, a chelating agent for complexation of iron ions, and a zinc immersion coating inhibitor, said zinc immersion coating inhibitor being at least one out of the group consisting of a polymer of a secondary amine, a polymer of a tertiary amine, and a polymer of a quaternary amine, or a copolymer containing the same, a step of immersing said material in an aqueous solution of nitric acid, a second zinc immersion coating step of immersing said material in a zinc immersion coating solution containing a zinc compound, an alkali hydroxide, an iron salt, a chelating agent for complexation of iron ions, and a zinc immersion coating inhibitor, said zinc immersion coating inhibitor being at least one out of the group consisting of a primary amine, a secondary amine, and a tertiary amine, and a plating step of forming a metal plating film by plating on said material after said second zinc immersion coating step.

In one embodiment of the method of forming a metal plating film according to the invention, the aforesaid zinc immersion coating solution used in the aforesaid first zinc immersion coating step contains the aforesaid zinc immersion coating inhibitor in an amount ranging from 0.05 to 50 g/L, and the aforesaid zinc immersion coating solution used in the aforesaid second zinc immersion coating step contains the aforesaid zinc immersion coating inhibitor in an amount ranging from 0.01 to 1 mol/L.

In another embodiment of the method of forming a metal plating film according to the invention, the aforesaid metal plating film is formed in the aforesaid plating step, using at least one plating method out of electroless plating, displacement plating, displacement/reduction plating, and electroplating, and said displacement/reduction plating may be carried out either in a plurality of baths in order of displacement plating and reduction plating or in a single bath in which displacement plating and reduction plating take place in parallel.

With such a method of forming a metal plating film as described above, it is possible to form on a material that is aluminum or an aluminum alloy a metal plating film having good enough appearance and sufficient adhesion strength.

Still further, the present invention provides a semiconductor device including an aluminum or aluminum alloy electrode and a metal plating film on said electrode, wherein said metal plating film has been formed by etching said electrode by an etching solution containing copper ions, then removing etching residues from said electrode using a stripping solution capable of dissolving copper, then immersing said electrode in a first zinc immersion coating solution, then immersing said electrode in an aqueous solution of nitric acid, then immersing said electrode in a second zinc immersion coating solution, and then applying plating to said electrode, said first zinc immersion coating solution containing at least a zinc compound, an alkali hydroxide, an iron salt, a chelating agent for complexation of iron ions, and a zinc immersion coating inhibitor that is at least one out of the group consisting of a polymer of a secondary amine, a polymer of a tertiary amine, and a polymer of a quaternary amine or a copolymer containing the same, and said second zinc immersion coating solution containing at least a zinc compound, an alkali hydroxide, an iron salt, a chelating agent for complexation of iron ions, and a zinc immersion coating inhibitor that is at least one out of the group consisting of a primary amine, a secondary amine and a tertiary amine.

In one embodiment of the semiconductor device according to the invention, the aforesaid first zinc immersion coating solution contains the aforesaid zinc immersion coating inhibitor in an amount ranging from 0.05 to 50 g/L, and the aforesaid second zinc immersion coating solution contains the aforesaid zinc immersion coating inhibitor in an amount ranging from 0.01 to 1 mol/L.

In another embodiment of the semiconductor device according to the invention, the aforesaid metal plating film is formed on the aforesaid electrode, using at least one plating method out of electroless plating, displacement plating, displacement/reduction plating, and electroplating, and said displacement/reduction plating may be carried out either in a plurality of baths in order of displacement plating and reduction plating or in a single bath in which displacement plating and reduction plating take place in parallel.

In the semiconductor device according to the invention, the aforesaid metal plating film may have a laminated structure in which a nickel plating film and a gold plating film are laminated together in order from the aforesaid electrode side, or a nickel plating film, a palladium plating film and a gold plating film are laminated together in order from the aforesaid electrode side. The aforesaid gold plating film may be formed by displacement/reduction plating in which displacement plating and reduction plating take place in order in a plurality of baths or in parallel in a single bath.

In such a semiconductor device as described above, the aluminum or aluminum alloy electrode includes a metal plating film having a good enough appearance and adequate adhesion strength.

### EXPLANATION OF THE PREFERRED EMBODIMENTS

The present invention is now explained with reference to some preferred embodiments.

The present inventors have made close studies of zinc immersion coating inhibitors, finding out that some zinc immersion coating inhibitors have strong inhibition on zinc immersion coating formation and strong adsorption to substances, and others have weak inhibition on zinc immersion coating formation and weak adsorption to substances. The inventors have further revealed that the addition of a zinc immersion coating inhibitor having strong adsorption to substances to a zinc immersion coating solution used for the second zinc immersion coating causes the zinc immersion coating inhibitor to remain adsorbed to the formed zinc immersion coating film, causing the zinc immersion coating inhibitor to be trapped in a plating bath, so resulting in adverse influences on the formation of a metal plating film. The present invention has been created on the basis of such to revealed results.

### [Zinc Immersion Coating Solutions]

The zinc immersion coating solutions according to the invention is used with the double-zincate method of applying the first and second zinc immersion coating treatments to aluminum or an aluminum alloy.

The zinc immersion coating solution used for the first zinc immersion coating treatment at least contains a zinc compound, an alkali hydroxide, an iron salt, a chelating agent for complexation of iron ions, and a zinc immersion coating inhibitor, and the zinc immersion coating inhibitor is at least one out of the group consisting of a polymer of a secondary amine, a polymer of a tertiary amine and a polymer of a quaternary amine or a copolymer containing the same. The zinc immersion coating solution used for the second zinc immersion coating treatment at least contains a zinc compound, an alkali hydroxide, an iron salt, a chelating agent for complexation of iron ions, and a zinc immersion coating inhibitor, and the zinc immersion coating inhibitor is at least one out of the group consisting of a primary amine, a secondary amine and a tertiary amine.

The zinc compound forming a part of the inventive zinc immersion coating solution used for the first zinc immersion coating treatment, for instance, includes zinc chloride, zinc oxide, zinc nitrate and zinc sulfate which may be used alone or in combination of two or more. The concentration of zinc in the zinc immersion coating solution used for the first zinc immersion coating treatment may range from 0.01 to 0.5 mol/L, and preferably 0.03 to 0.15 mol/L.

The alkali hydroxide forming a part of the inventive zinc immersion coating solution used for the first zinc immersion coating treatment, for instance, includes potassium hydroxide, sodium hydroxide and lithium hydroxide which may be used alone or in combination of two or more. The concentration of the alkali hydroxide in the zinc immersion coating solution used for the first zinc immersion coating treatment may range from 1 to 6 mol/L, and preferably 2 to 4 mol/L.

The iron salt forming a part of the inventive zinc immersion coating solution used for the first zinc immersion coating treatment includes starting with ferric chloride, iron chloride, iron nitrate, iron phosphate, iron cyanide, iron bromide, and organic acid iron such as iron acetate, citrate and lactate, which may be used alone or in combination of two or more. The concentration of iron in the zinc immersion coating solution used for the first zinc immersion coating treatment may range from 0.1 to 10 mmol/L, and preferably 0.3 to 5 mmol/L.

The chelating agent forming a part of the inventive zinc immersion coating solution used for the first zinc immersion coating treatment, for instance, includes gluconic acid. Such gluconic acid may have the delivery form of, in addition to gluconic acid, gluconates such as sodium gluconate and potassium gluconate. The content of gluconic acid in the zinc immersion coating solution used for the first zinc immersion coating treatment is at least 20 times as high as iron ions in molar ratio, and preferably the molar ratio of iron ions to gluconic acid may be set in a range of 1:20 to 1:200.

The zinc immersion coating inhibitor forming a part of the inventive zinc immersion coating solution used for the first zinc immersion coating treatment is at least one out of the group consisting of a polymer of a secondary amine, a polymer of a tertiary amine and a polymer of a quaternary amine or a copolymer containing that polymer. Such zinc immersion coating inhibitors, for instance, include a diallylamine hydrochlorate polymer, a methyldiallylamine hydrochlorate polymer, a dimethyldiallylammonium chloride polymer, a diallylamine hydrocylorate.sulfur dioxide copolymer, a methyldiallylamine hydrochlorate.sulfur dioxide copolymer, and a dimethyldiallylammonium chloride.sulfur dioxide copolymer, among which the dimethyldiallylammonium chloride.sulfur dioxide copolymer is most preferred. The content of the zinc immersion coating inhibitor in the zinc immersion coating solution used for the first zinc immersion coating treatment ranges from 0.05 to 50 g/L, and preferably 0.1 to 5 g/L. As the content of the zinc immersion coating inhibitor is less than 0.05 g/L, it is not preferable because the action on inhibition of zinc displacement in the first zinc immersion coating treatment remains less than satisfactory, and as the content is greater than 50 g/L, it is not again preferable because the bath's service life becomes short.

If necessary, tartrates, nitrates or surfactants may be added in an amount ranging from 0.01 to 300 g/L to the inventive zinc immersion coating solution used for the first zinc immersion coating treatment.

Next, the zinc compound forming a part of the inventive zinc immersion coating solution used for the second zinc immersion coating treatment, for instance, includes zinc chloride, zinc oxide, zinc nitrate and zinc sulfate which may be used alone or in combination of two or more. The concentration of zinc in the zinc immersion coating solution used for the second zinc immersion coating treatment may range from 0.01 to 0.5 mol/L, and preferably 0.03 to 0.15 mol/L.

The alkali hydroxide forming a part of the inventive zinc immersion coating solution used for the second zinc immersion coating treatment, for instance, includes potassium hydroxide, sodium hydroxide and lithium hydroxide which may be used alone or in combination of two or more. The concentration of the alkali hydroxide in the zinc immersion coating solution used for the second zinc immersion coating treatment may range from 1 to 6 mol/L, and preferably 2 to 4 mol/L.

The iron salt forming a part of the inventive zinc immersion coating solution used for the second zinc immersion coating treatment includes starting with ferric chloride, iron chloride, iron nitrate, iron phosphate, iron cyanide, iron bromide, and organic acid iron such as iron acetate, citrate and lactate, which may be used alone or in combination of two or more. The concentration of iron in the zinc immersion coating solution used for the second zinc immersion coating treatment may range from 1 to 50 mmol/L, and preferably 5 to 25 mmol/L. It is then preferable that the concentration of iron ions in the zinc immersion coating solution used for the second zinc immersion coating treatment is higher than that in the zinc immersion coating solution used for the first zinc immersion coating treatment.

The chelating agent forming a part of the inventive zinc immersion coating solution used for the second zinc immersion coating treatment, for instance, includes gluconic acid and tartrates. The content of the chelating agent in the zinc immersion coating solution used for the second zinc immersion coating treatment may be set to less than 20 times as high as iron ions in molar ratio.

Further, the zinc immersion coating inhibitor forming a part of the inventive zinc immersion coating solution used for the second zinc immersion coating treatment is at least one out of the group consisting of primary, secondary and tertiary amines. Such a zinc immersion coating inhibitor has weak adsorption to substances although it has low action on inhibition of zinc immersion. Thus, if the zinc immersion coating inhibitor added to the zinc immersion coating solution used for the second zinc immersion coating treatment is formed of at least one out of the groups consisting of primary, secondary and tertiary amines, it is then possible to inhibit adsorption of the zinc immersion coating inhibitor to the zinc immersion coating film formed by the second zinc immersion coating treatment. Such a zinc immersion coating inhibitor, for instance, includes ethylenediamine, diethylenetriamine, triethylenetetramine, ethanolamine, diethanolamine and triethanolamine, among which triethylenetetramine is most preferable. The content of the zinc immersion coating inhibitor in the zinc immersion coating solution used for the second zinc immersion coating treatment may range from 0.01 to 1 mol/L, and preferably 0.02 to 0.5 mol/L. As the content of the zinc immersion coating inhibitor is less than 0.01 mol/L, it is not preferable because the action on inhibition of zinc displacement in the second zinc immersion coating treatment remains less than satisfactory, and as the content is greater than 1 mol/L, it is not again preferable because zinc displacement is too much inhibited, ending up with poor adhesion.

If necessary, tartrates, nitrates, copper salts, nickel salts, cobalt salts, and surfactants may be added in an amount ranging from 0.01 to 300 g/L to the inventive zinc immersion coating solution used for the second zinc immersion coating treatment.

The zinc immersion coating solutions according to the invention have their composition optimized for the first and second zinc immersion coating treatments that are each a pre-plating treatment for aluminum or aluminum alloys to which the double-zincate method is to be applied. With those coating solutions it is possible to obtain a uniform, dense plated zinc coating film while preventing pitting, and hold back any adsorption of the zinc immersion coating inhibitor to the zinc coating film.

There is no particular limitation on conditions under which zinc immersion coating is carried out using the zinc immersion coating solutions according to the invention; for instance, the bath temperature may be set in a range of 10 to 40° C. As the bath temperature is lower than 10° C., it is not preferable because the displacement reaction involved is likely to get too slow to bring about zincate variations, and as the bath temperature is higher than 40° C., it is again not preferable because the zinc immersion coating reaction is increased so much so that there is an increase in surface roughness.

The aluminum alloy for which the zinc immersion coating solutions of the invention are used, for instance, includes an aluminum-silicon alloy, an aluminum-copper alloy, an aluminum-silicon-copper alloy, and an aluminum-neodymium alloy.

### [Double-Zincate Method]

With the double-zincate method of the invention, applying the first and second zinc immersion coating treatments to aluminum or an aluminum alloy, thereby it is possible to form a metal plating film.

The double-zincate method of the invention includes a first zinc immersion coating step of immersing an aluminum or aluminum alloy material in a zinc immersion coating solution, a step of immersing the material going through the first zinc immersion coating step in an aqueous solution of nitric acid thereby stripping off the zinc coating film, and a second zinc immersion coating step of immersing the material in a zinc immersion coating solution to form the zinc coating film on the surface of the material.

The zinc immersion coating solution used in the first zinc immersion coating step of the double-zincate method according to the invention at least contains a zinc compound, an alkali hydroxide, an iron salt, a chelating agent for complexation of iron ions, and a zinc immersion coating inhibitor. The zinc immersion coating inhibitor contained in this zinc immersion coating solution is at least one out of the group consisting of a polymer of a secondary amine, a polymer of a tertiary amine and a polymer of a quaternary amine or a copolymer containing the same.

The zinc immersion coating solution used in the second zinc immersion coating step at least contains a zinc compound, an alkali hydroxide, an iron salt, a chelating agent for complexation of iron ions, and a zinc immersion coating inhibitor. The zinc immersion coating inhibitor contained in this zinc immersion coating solution is at least one out of the group consisting of primary, secondary and tertiary amines.

The aforesaid zinc immersion coating solution of the invention may be used for the zinc immersion coating solution used in the first zinc immersion coating step, and the zinc immersion coating solution used in the second zinc immersion coating step; so detailed explanations of them are left out.

There is no particular limitation on the immersion conditions under which the material is immersed in the zinc immersion coating solution in the first and second zinc immersion coating steps; for instance, the bath temperature may be set in a range of 10 to 40° C.

Prior to the aforesaid first zinc immersion coating step, the double-zincate method of the invention may optionally include an etching step of etching the aluminum or aluminum alloy material by an etching solution containing copper ions, and a residue removal step of removing etching residues from the etched aluminum or aluminum alloy material using a stripping solution capable of dissolving copper. As the double-zincate method of the invention includes such etching and residue removal steps, it ensures that the metal plating film formed on the aluminum or aluminum alloy material by electroless plating or electroplating provides a nodule-free film having good-enough adhesion and appearance.

Preferably, the concentration of copper in the etching solution used in the aforesaid etching step ranges from 2 to 1,000 mg/L, and especially 10 to 100 mg/L. As the concentration of copper is less than 2 mg/L or greater than 1,000 mg/L, it often makes the formed nickel film likely to have nodules, resulting in poor adhesion and defective film appearance. The etching solution containing copper ions in such a concentration range includes an acidic solution containing sulfuric acid and/or phosphoric acid, and an alkali solution containing a copper complexing agent and a pH value of at least 8 or the like, among which a sulfuric acid solution is most preferred. An alkali solution containing a copper complexing agent has a pH range of preferably 8 to 13, because the advantages of the invention will not be achievable by an alkali solution having a pH range of up to 8, and aluminum will possibly be strongly etched in a pH range greater than 13.

It is here to be noted that the aforesaid etching solution may contain a surfactant or the like in a range of 0.01 to 10% by weight.

There is no particular limitation on the temperature of the etching solution at the time of etching on the aluminum or aluminum alloy material; for instance, an appropriate choice may be made from the range of 20 to 80° C.

The stripping solution used in the aforesaid residue removal step has the ability to dissolve copper; for instance, it is desired to contain a copper oxidizing agent in a concentration range of 1 g/L or more, and preferably 5 to 200 g/L. The copper oxidizing agent includes persulfates such as potassium persulfate, sodium persulfate and ammonium persulfate, hydrogen peroxide, nitric acid, etc., among which the persulfates and hydrogen peroxide are most preferred. AS the concentration of the copper oxidizing agent in the stripping solution is less than 1 g/L, it is not preferable because there are nodules appearing on the metal plating film formed after the double-zincate processing, resulting in poor adhesion and poor film appearance. There is no upper limit to the concentration of the oxidizing agent; in other words, an appropriate choice may be made from the range including the maximum (saturation) concentration depending on various oxidizing agents. Such a stripping solution may optionally be an aqueous solution containing the aforesaid copper oxidizing agent in the aforesaid range. A solution containing a mixture of methanesulfonic acid and thiourea as a copper complexing agent, too, may be used as the aforesaid stripping solution because the dissolved oxygen functions as an oxidizing agent.

In the invention, an alkali etching solution composed mainly of copper ions, anions and ammonia may also be used as the stripping solution capable of dissolving copper. The anions include chlorine ions, sulfate ions, carbonate ions or the like. Preferably, this alkali etching solution has a copper ion concentration on the order of 1.5 to 2.5 mol/L, an anion concentration on the order of 3.0 to 5.0 mol/L, and an ammonia concentration on the order of 6 to 10 mol/L.

There is no particular limitation on the temperature of the stripping solution upon stripping (removal of etching residues); for instance, an appropriate choice may be made from the range of 10 to 50° C. It is here to be noted that the aforesaid stripping solution may optionally contain an inorganic acid such as sulfuric acid, an organic acid such as methanesulfonic acid, a surfactant, etc. in an amount ranging from 0.01 to 10% by weight.

According to the double-zincate method of the invention, both the first and second zinc immersion coating treatments can prevent pitting of aluminum or aluminum alloys, and allow for the formation of a uniform, dense plated zinc immersion coating film, and any adsorption of the zinc immersion coating inhibitor onto the zinc immersion coating film formed by the second zinc immersion coating treatment can be held back. This in turn allows for prevention of trapping of the zinc immersion coating inhibitor into the plating bath at the time of metal plating onto the zinc immersion coating film.

The aluminum alloys, to which the double-zincate method of the invention is to be applied, may be exemplified by an aluminum-silicon alloy, an aluminum-copper alloy, an aluminum-silicon-copper alloy, and an aluminum-neodymium.

### [Method of Forming Metal Plating Film]

According to the inventive method of forming a metal coating film, there is a metal plating film formed on the aluminum or aluminum alloy material.

The method of the invention comprises an etching step of etching an aluminum or aluminum alloy material by an etching solution containing copper ions, a residue removal step of removing etching residues from the etched aluminum or aluminum alloy material using a stripping solution capable of dissolving copper, a first zinc immersion coating step of immersing the material, from which residues have been removed, in a zinc immersion coating solution, a step of immersing the material going through the first zinc immersion coating step in an aqueous solution of nitric acid to strip off a zinc immersion coating film, a second zinc immersion coating step of immersing the material in a zinc immersion coating solution to form a zinc immersion coating film on the surface of the material, and a plating step of forming a metal plating film on the material by plating after the second zinc immersion coating step.

In the invention, the steps from the etching step up to the second zinc immersion coating step may each be carried out in the same manner as is the case with the double-zincate method of the invention; so detailed explanations of them will be left out.

Likewise, the zinc immersion coating solution used in the first zinc immersion coating step, and the zinc immersion coating solution used in the second zinc immersion coating step may be the same as the aforesaid zinc immersion coating solutions of the invention; so detailed explanations of them will be left out.

In the plating step of the invention, a metal plating film may be formed by at least one plating method out of electroless plating, displacement plating, displacement/reduction plating, and electroplating. Which plating method is to be used may appropriately be determined in consideration of the metal species to be plated, the plating thickness, etc.

Typical electroless plating may be carried out by immersing a material in a plating bath containing ions of the metal to be plated such as nickel. In this electro-less plating, nickel or the like reduced by a reduction catalyst is deposited and grown to form a metal plating film. For the plating solution, the known plating solutions containing ions of the metal to be plated can be used, with no limitation imposed on their composition. The metal plating film thickness may optionally be determined depending on the properties of the film demanded; so it may be on the order of 0.5 to 20 μm. The temperature and immersion time of the electro-less plating solution used may optionally be determined depending on the thickness, etc. of the metal plating film to be formed.

Displacement plating may be exemplified by displacement palladium plating, displacement gold plating, displacement silver plating or other like plating on the nickel plating film formed by electroless plating.

For displacement/reduction plating, by way of example, a plurality of baths may be used to apply displacement plating and reduction plating sequentially on the nickel plating film formed by electroless plating or, alternatively, a single bath may be used to apply displacement plating and reduction plating on it in parallel. Such displacement/reduction plating may be applied even on the thin nickel plating film, because it is possible to form a thick gold plating film without bringing about defects such as peeling of that nickel plating film. Such displacement/reduction plating may be applied to palladium plating and silver plating too.

The reducing agent used for displacement/reduction plating, for instance, includes ascorbic acid or its salts, glyoxylic acid or its salts, thiourea or its derivatives, hydrazines, boron hydride compounds, amine boranes, formaldehyde, and formic acid or its salts. The salts of the aforesaid ascorbic acid, glyoxylic acid and formic acid include sodium salts, potassium salts, ammonium salts, etc. The aforesaid thiourea derivatives include 1,3-dimethylthiourea, trimethylthiourea, thio-semicarbazide, 1-phenylthiourea, thiourea dioxide, etc., and the aforesaid hydrazines include hydrazine sulfate, hydrazine hydrates, methylhydrazine, etc. Further, the aforesaid boron hydride compound includes sodium borohydride, potassium borohydride, etc., and the aforesaid amine boranes include dimethylamine borane, trimethylamine borane, etc.

For the formation of the metal plating film by electroplating, electric currents may be fed through the material immersed as a cathode in a plating solution containing ions of the metal to be plated such as nickel or gold. The metal plating film is formed on the surface of the zinc immersion coating film formed in the second zinc immersion coating step, and its thickness may optionally be determined depending on the properties demanded for the metal plating film; for instance, the thickness may be on the order of 1 to 50 μm. Likewise, the electroplating conditions for the formation of the metal plating film may optionally be determined depending on the thickness, etc. of the formed metal plating film.

In the invention, there may be an underplate layer provided prior to the formation of the metal plating film by electroless plating, displacement plating or electroplating in the plating step. This underplate layer may be provided for the purpose of improving the adhesion of the metal plating film to be formed in the later steps and homogenizing the surface of the zinc immersion coating film formed in the second zinc immersion coating step. In other words, if an adhesion of the metal plating film applied directly on the zinc immersion coating film formed in the second zinc immersion coating step is low, it is possible to form a metal plating film having good enough adhesion by appropriate selection of the type of the metal forming the underplate layer. The underplate layer may be formed by electroplating in a plating solution containing copper ions as an example, with the material immersed as a cathode in it. The underplate layer is formed on the zinc immersion coating film, and its thickness may be determined in consideration of the metal material of the underplate layer, the metal material of the metal plating film formed in the later steps, the shape of the material, etc. For instance, that thickness may be on the order of 10 to 1,000 nm. Likewise, the electroplating conditions for the formation of the underplate layer may optionally be determined depending on the thickness of the underplate layer to be formed.

With the process of forming a metal plating film according to the invention, it is possible to form a metal plating film having good enough appearance and adequate adhesion strength, on the aluminum or aluminum alloy material.

The aluminum alloy to which the method of forming a metal plating film according to the invention is applied, for instance, includes an aluminum-silicon alloy, an aluminum-copper alloy, an aluminum-silicon-copper alloy, and an aluminum-neodymium alloy.

### [Semiconductor Device]

The semiconductor device of the invention includes a plurality of electrodes, all or a part of which are aluminum or aluminum alloy electrodes having a metal plating film plated on it.

The aluminum alloy as the electrode, for instance, may be an aluminum-silicon alloy, an aluminum-copper alloy, an aluminum-silicon-copper alloy, and an aluminum-neodymium alloy.

The metal plating film on the aluminum or aluminum alloy electrode, for instance, may be a nickel plating film, a gold plating film, a silver plating film, a copper plating film, a palladium plating film, a cobalt plating film, and an alloy plating film composed mainly of these metals, or a laminated film comprising a combination of two or more such plating films.

The aluminum or aluminum alloy electrode forming a part of the semiconductor device according to the invention may have a thickness on the order of 0.2 to 5 μm as an example, and the thickness of the metal plating film on the electrode may optionally be determined from a range of, for instance, about 10 nm to 50 μm, depending on the properties demanded for the metal plating film.

The metal plating film on the aluminum or aluminum alloy electrode has been formed as follows. First, the aluminum or aluminum alloy electrode is etched by an etching solution containing copper ions, and then etching residues are removed from the electrode using a stripping solution capable of dissolving copper. Then, the electrode is immersed in the first zinc immersion coating solution, after which the electrode is immersed in an aqueous solution of nitric acid to strip off a zinc immersion coating film. Then, the electrode is immersed in the second zinc immersion coating solution to form a zinc immersion coating film. Then, the electrode is plated to form the metal plating film.

The aforesaid first zinc immersion coating solution at least contains a zinc compound, an alkali hydroxide, an iron salt, a chelating agent for complexation of iron ions, and a zinc immersion coating inhibitor that is at least one out of the group consisting of a polymer of a secondary amine, a polymer of a tertiary amine, and a polymer of a quaternary amine, or a copolymer containing the same. The aforesaid second zinc immersion coating solution at least contains a zinc compound, an alkali hydroxide, an iron salt, a chelating agent for complexation of iron ions, and a zinc immersion coating inhibitor that is at least one out of the group consisting of a primary amine, a secondary amine and a tertiary amine.

The metal plating film on the aluminum or aluminum alloy electrode may be formed in the same manner as the aforesaid method of forming a metal plating film according to the invention; so any detailed explanation will be left out.

In the semiconductor device of the invention, the aluminum or aluminum alloy electrode is provided thereon with the metal plating film having good enough appearance and sufficient adhesion strength. It is then possible to achieve a semiconductor device using aluminum or an aluminum alloy as interconnecting wires as an example and comprising electrodes having good enough solder wettability.

### EXAMPLES

The present invention will now be explained in further details with reference to examples.

### Example 1

An aluminum-silicon alloy thin film (having a silicon content of 1.0% by weight and a thickness of 0.7 μm) was provided on a glass substrate with magnetron sputtering process.

Then, the aforesaid glass substrate was degreased using Melcleaner SC-7001 from Meltex Inc. (a solution temperature of 70° C.), and rinsed.

Then, an etching solution was prepared by adding copper sulfate.pentahydrate to a 50% by volume aqueous solution of sulfuric acid such that the copper concentration was 100 mg/L (a solution temperature of 70° C.) And the glass substrate was immersed in this etching solution for 3 minutes to apply etching to the aluminum-silicon alloy film, and then rinsed.

The aluminum-silicon alloy film treated by the aforesaid etching was immersed in an aqueous solution containing potassium persulfate in a concentration of 100 g/L (a solution temperature of 25° C.) for 3 minutes for removal of etching residues.

Then, the zinc immersion coating solution used for the first zinc immersion coating treatment was prepared with the following composition.

### (Composition of the Zinc Immersion Coating Solution for the First Zinc Immersion Coating Treatment)

| | | |
|---|---|---|
| Zinc Oxide | 0.15 | mol/L |
| Sodium Hydroxide | 2.4 | mol/L |
| Ferric Chloride | 0.002 | mol/L |
| Gluconic Acid | 0.2 | mol/L |
| Zinc Immersion Coating Inhibitor | 0.65 | g/L |
| (dimethyldiallylammonium chloride•sulfur dioxide | | |
| copolymer) | | |

Further, the zinc immersion coating solution used for the second zinc immersion coating treatment was prepared with the following composition.

### (Composition of the Zinc Immersion Coating Solution for the Second Zinc Immersion Coating Treatment)

| | | |
|---|---|---|
| Zinc Oxide | 0.15 | mol/L |
| Sodium Hydroxide | 2.4 | mol/L |
| Ferric Chloride | 0.008 | mol/L |
| Gluconic Acid | 0.2 | mol/L |
| Zinc Immersion Coating Inhibitor (triethylenetetramine) | 0.07 | mol/L |

The glass substrate going through the aforesaid etching residue removal step was immersed in the aforesaid zinc immersion coating solution for the first zinc immersion coating treatment for 1 minute (a solution temperature of 22° C.) to carry out the first zinc immersion coating, and then rinsed. Thereafter, a zinc immersion coating film was stripped off using a 50% by volume aqueous solution of nitric acid, and rinsed. The glass substrate was immersed in the zinc immersion coating solution for the aforesaid second zinc immersion coating treatment for 0.5 minute (a solution temperature of 22° C.) to carry out the second zinc immersion coating, and then rinsed thereby forming a zinc immersion coating film on the aluminum-silicon alloy film on the glass substrate. As a result of measuring the surface roughness of that film after the aforesaid first zinc immersion coating treatment using DEKTAK 3ST from ULVAC Inc., it was found to have an average surface roughness Ra of 0.20 μm, and an average surface roughness Ra of 0.10 μm after the second zinc immersion coating treatment, and any local corrosion was not observed on the aluminum-silicon alloy thin film.

Then, the glass substrate was immersed in Melplate NI-869 (a solution temperature of 85° C. and pH 4.3) from Meltex Inc. for 20 minutes to apply electroless plating treatment to it, and rinsed.

Then, the glass substrate was immersed in Melplate AU-7621 (a solution temperature of 80° C. and pH 4.6) from Meltex Inc. for 20 minutes to apply displacement gold plating treatment to it, and rinsed.

By way of the aforesaid operations, a metal plating film comprising a 5 μm-thick nickel film and a 0.05 μm-thick gold thin film was formed on the aluminum-silicon alloy thin film. This metal plating film had good enough adhesion to the aluminum-silicon alloy thin film, and the thickness loss of the aluminum-silicon alloy thin film after the formation of the metal plating film was 0.01 μm. As a result of measuring the surface roughness of the formed metal plating film as described above, the average surface roughness Ra was 0.08 μm, indicating that the film surface had good enough smoothness.

It is here to be noted that the thickness of the metal plating film was measured using DEKTAK 3ST from ULVAC Inc. or SEA-5120 from Seiko Instruments Inc. The same will hold hereinafter.

### Comparative Example 1

A zinc immersion coating solution having the following zinc immersion coating inhibitor-free composition was prepared as the zinc immersion coating solution for the first zinc immersion coating treatment.

### (Composition of the Zinc Immersion Coating Solution for the First Zinc Immersion Coating Treatment)

| | |
|---|---|
| Zinc Oxide | 0.15 mol/L |
| Sodium Hydroxide | 2.4 mol/L |
| Ferric Chloride | 0.002 mol/L |
| Gluconic Acid | 0.2 mol/L |

Example 1 was repeated with the exception that this immersion coating solution was used for the first zinc immersion coating treatment to form a metal plating film comprising a nickel film and a gold thin film on the aluminum-silicon alloy thin film.

As a result of measuring the surface roughness after the second zinc immersion coating treatment in the double-zincate process, however, the average surface roughness Ra was 0.36 μm, a figure much greater than the result of measurement in Example 1 (0.20 μm). The formed metal plating film had noticeable nodules and was found to have an average surface roughness Ra of 0.18 μm, a figure much greater than the result of measurement in Example 1 (0.08 μm). Furthermore, the thickness loss of the aluminum-silicon alloy film after the formation of the metal plating film was 0.05 μm, a figure much greater than the result of measurement in Example 1 (0.01 μm).

### Comparative Example 2

A zinc immersion coating solution having the following zinc immersion coating inhibitor-free composition was prepared as the zinc immersion coating solution for the second zinc immersion coating treatment.

### (Composition of the Zinc Immersion Coating Solution for the Second Zinc Immersion Coating Treatment)

| | |
|---|---|
| Zinc Oxide | 0.15 mol/L |
| Sodium Hydroxide | 2.4 mol/L |
| Ferric Chloride | 0.008 mol/L |
| Gluconic Acid | 0.2 mol/L |

Example 1 was repeated with the exception that this immersion coating solution was used for the second zinc immersion coating treatment to form a metal plating film comprising a nickel film and a gold thin film on the aluminum-silicon alloy thin film.

As a result of measuring the surface roughness after the second zinc immersion coating treatment in the double-zincate process, however, the average surface roughness Ra was 0.19 μm, a figure much greater than the result of measurement in Example 1 (0.10 μm). The formed metal plating film had noticeable nodules and was found to have an average surface roughness Ra of 0.16 μm, a figure much greater than the result of measurement in Example 1 (0.08 μm).

### Comparative Example 3

A zinc immersion coating solution having the following composition having a different zinc immersion coating inhibitor was prepared as the zinc immersion coating solution for the first zinc immersion coating treatment.

### (Composition of the Zinc Immersion Coating Solution for the First Zinc Immersion Coating Treatment)

| | |
|---|---|
| Zinc Oxide | 0.15 mol/L |
| Sodium Hydroxide | 2.4 mol/L |
| Ferric Chloride | 0.002 mol/L |
| Gluconic Acid | 0.2 mol/L |
| Zinc Immersion Coating Inhibitor (triethylenetetramine) | 0.07 mol/L |

Example 1 was repeated with the exception that this immersion coating solution was used for the first zinc immersion coating treatment to form a metal plating film comprising a nickel film and a gold thin film on the aluminum-silicon alloy thin film.

As a result of measuring the surface roughness after the first zinc immersion coating treatment in the double-zincate process, however, the average surface roughness Ra was 0.29 μm, a figure much greater than the result of measurement in Example 1 (0.20 μm). The formed metal plating film had noticeable nodules and was found to have an average surface roughness Ra of 0.15 μm, a figure much greater than the result of measurement in Example 1 (0.08 μm). Furthermore, the thickness loss of the aluminum-silicon alloy film after the formation of the metal plating film was 0.03 μm, a figure much greater than the result of measurement in Example 1 (0.01 μm).

### Comparative Example 4

A zinc immersion coating solution having the following composition having a different zinc immersion coating inhibitor was prepared as the zinc immersion coating solution for the second zinc immersion coating treatment.

### (Composition of the Zinc Immersion Coating Solution for the Second Zinc Immersion Coating Treatment)

| | | |
|---|---|---|
| Zinc Oxide | 0.15 | mol/L |
| Sodium Hydroxide | 2.4 | mol/L |
| Ferric Chloride | 0.008 | mol/L |
| Gluconic Acid | 0.2 | mol/L |
| Zinc Immersion Coating Inhibitor | 0.65 | g/L |
| (dimethyldiallylammonium chloride•sulfur dioxide | | |
| copolymer) | | |

Example 1 was repeated with the exception that this immersion coating solution was used for the second zinc immersion coating treatment to form a metal plating film comprising a nickel film and a gold thin film on the aluminum-silicon alloy thin film.

However, the formed metal plating film was observed to have anomalous deposition where there was locally no plating deposition.

### Comparative Example 5

A zinc immersion coating solution having the following composition was prepared as the zinc immersion coating solution for the first zinc immersion coating treatment.

### (Composition of the Zinc Immersion Coating Solution for the First Zinc Immersion Coating Treatment)

| | |
|---|---|
| Zinc Oxide | 0.15 mol/L |
| Sodium Hydroxide | 2.4 mol/L |
| Ferric Chloride | 0.008 mol/L |
| Gluconic Acid | 0.2 mol/L |
| Zinc Immersion Coating Inhibitor (triethylenetetramine) | 0.07 mol/L |

Further, a zinc immersion coating solution having the following composition was prepared as the zinc immersion coating solution for the second zinc immersion coating treatment.

### (Composition of the Zinc Immersion Coating Solution for the Second Zinc Immersion Coating Treatment)

| | | |
|---|---|---|
| Zinc Oxide | 0.15 | mol/L |
| Sodium Hydroxide | 2.4 | mol/L |
| Ferric Chloride | 0.002 | mol/L |
| Gluconic Acid | 0.2 | mol/L |
| Zinc Immersion Coating Inhibitor | 0.65 | g/L |
| (dimethyldiallylammonium chloride•sulfur dioxide | | |
| copolymer) | | |

Example 1 was repeated with the exception that these coating solutions were used for the first and second zinc immersion coating treatments to form a metal plating film comprising a nickel film and a gold thin film on the aluminum-silicon alloy thin film.

As a result of measuring the surface roughness after the first zinc immersion coating treatment in the double-zincate process, however, there was an average surface roughness Ra of 0.36 μm found, a figure much greater than the result of measurement in Example 1 (0.20 μm). Further, the formed metal plating film was found to have anomalous deposition where there was locally no plating deposition, and the adhesion of the nickel film to the aluminum-silicon alloy thin film was found to be poor. Furthermore, the thickness loss of the aluminum-silicon alloy thin film after the formation of the metal plating film was 0.04 μm, a figure much greater than the result of measurement in Example 1 (0.01 μm).

### Example 2

An aluminum-silicon alloy thin film was formed on a glass substrate as in Example 1, and decreasing, etching, etching residue removal, the first and second zinc immersion coating treatments were carried out as in Example 1 whereby a zinc immersion coating film was formed on the aluminum-silicon alloy film on the glass substrate. It is here to be noted that the average surface roughness Ra after the first and second zinc immersion coating treatments was 0.20 μm and 0.10 μm, respectively, and there was no local corrosion observed on the aluminum-silicon alloy thin film.

Then, the glass substrate was immersed in Melplate NI-869 (a solution temperature of 85° C. and pH 4.3) from Meltex Inc. for 4 minutes to apply electroless nickel plating treatment to it, and rinsed.

Then, the glass substrate was immersed in a displacement/reduction gold plating bath having the following composition (a solution temperature of 65° C. and pH 9.0) for 12 minutes for displacement/reduction plating, and rinsed.

### (Composition of the Displacement/Reduction Plating Bath)

| | |
|---|---|
| Gold Sodium Sulfite | 0.005 mol/L |
| Sodium Sulfite | 0.04 mol/L |
| Sodium Ethylenediaminetetraacetate | 0.026 mol/L |
| Reducing Agent (thiourea derivative) | 0.13 mol/L |
| Sodium Hydroxide (pH adjustment) | as appropriate |

By way of the aforesaid operations, a metal plating film comprising a 1 μm-thick nickel film and a 0.1 μm-thick gold thin film was formed on the aluminum-silicon alloy thin film. This metal plating film had good enough adhesion to the aluminum-silicon alloy thin film, and the thickness loss of the aluminum-silicon alloy thin film after the formation of the metal plating film was 0.01 μm. As a result of measuring the surface roughness of the formed metal plating film as described above, the average surface roughness Ra was 0.09 μm, indicating that the film surface had good enough smoothness.

### Comparative Example 6

The processes from decreasing to electroless nickel plating treatment were carried out as in Example 2 to form a 1-μm thick nickel film.

Then, the glass substrate was immersed in Melplate AU-6601 (a solution temperature of 90° C. and pH 5.0) from Meltex Inc. for 20 minutes to apply displacement gold plating treatment to it, and rinsed whereby a metal plating film comprising a 1-μm thick nickel film and a 0.1-μm thick gold film was formed on the aluminum-silicon alloy thin film.

However, the metal plating film formed on the aluminum-silicon alloy thin film was not only found to be peeled off at its edge but also found to have poor adhesion to the aluminum-silicon alloy thin film. From this result and the results of Example 1 (the nickel film having a thickness of 5 μm) and Example 2, it has been found that when the nickel film is relatively thin, it is preferable that a gold thin film formed on this nickel film is provided by displacement/reduction plating.

What is claimed is:

1. A zinc immersion coating solution used with a double-zincate method in which a first zinc immersion coating treatment and a second zinc immersion coating treatment are applied to aluminum or an aluminum alloy, wherein:
a zinc immersion coating solution used for the first zinc immersion coating treatment at least contains a zinc compound, an alkali hydroxide, an iron salt, a chelating agent for complexation of iron ions, and a zinc immersion coating inhibitor, said zinc immersion coating inhibitor being at least one out of the group consisting of a polymer of a secondary amine, a polymer of a tertiary amine, and a polymer of a quaternary amine, or a copolymer containing the same, and a zinc immersion coating solution used for the second zinc immersion coating treatment at least contains a zinc compound, an alkali hydroxide, an iron salt, a chelating agent for complexation of iron ions, and a zinc immersion coating inhibitor, said zinc immersion coating inhibitor being at least one out of the group consisting of a primary amine, a secondary amine, and a tertiary amine.

2. The zinc immersion coating solution of claim 1, wherein said zinc immersion coating solution used for the first zinc immersion coating treatment contains said zinc immersion coating inhibitor in an amount ranging from 0.05 to 50 g/L, and said zinc immersion coating solution used for the second zinc immersion coating treatment contains said zinc immersion coating inhibitor in an amount ranging from 0.01 to 1 mol/L.

3. The zinc immersion coating solution of claim 1, wherein the chelating agent in said zinc immersion coating solution used for the first zinc immersion coating is gluconic acid, the content of which is at least 20 times as high as iron ions in molar ratio.

4. The zinc immersion coating solution of claim 1, wherein said zinc immersion coating solution used for the first zinc immersion coating has a zinc concentration ranging from 0.01 to 0.5 mol/L.

5. The zinc immersion coating solution of claim 1, wherein said zinc immersion coating solution used for the first zinc immersion coating has an alkali hydroxide concentration ranging from 1 to 6 mol/L.

6. The zinc immersion coating solution of claim 1, wherein said zinc immersion coating solution used for the first zinc immersion coating has an iron concentration ranging from 0.1 to 10 mmol/L.

7. A double-zincate method for applying a first zinc immersion coating treatment and a second zinc immersion coating treatment to a material that is aluminum or an aluminum alloy, comprising:
a first zinc immersion coating step of immersing said material in a zinc immersion coating solution at least containing a zinc compound, an alkali hydroxide, an iron salt, a chelating agent for complexation of iron ions, and a zinc immersion coating inhibitor, said zinc immersion coating inhibitor being at least one out of the group consisting of a polymer of a secondary amine, a polymer of a tertiary amine, and a polymer of a quaternary amine, or a copolymer containing the same,
a step of immersing said material in an aqueous solution of nitric acid, and
a second zinc immersion coating step of immersing said material in a zinc immersion coating solution at least containing a zinc compound, an alkali hydroxide, an iron salt, a chelating agent for complexation of iron ions, and a zinc immersion coating inhibitor, said zinc immersion coating inhibitor being at least one out of the group consisting of a primary amine, a secondary amine, and a tertiary amine.

8. The double-zincate method of claim 7, wherein said zinc immersion coating solution used in said first zinc immersion coating step contains said zinc immersion coating inhibitor in an amount ranging from 0.05 to 50 g/L, and said zinc immersion coating solution used in said second zinc immersion coating step contains said zinc immersion coating inhibitor in an amount ranging from 0.01 to 1 mol/L.

9. The double-zincate method of claim 7, which, prior to said first zinc immersion coating step, further comprises an etching step of etching said material by an etching solution containing copper ions, and a residue removal step of removing etching residues from said material going through said etching step, using a stripping solution capable of dissolving copper.

10. The double-zincate method of claim 9, wherein said etching solution has a copper concentration ranging from 2 to 1,000 mg/L.

11. The double-zincate method of claim 9, wherein said etching solution is either an acidic solution containing sulfuric acid and/or phosphoric acid or an alkali solution containing a copper complexing agent and having a pH value of at least 8.

12. The double-zincate method of claim 9, wherein said stripping solution contains as a copper oxidizing agent at least one of nitric acid, a persulfate, and hydrogen peroxide.

13. The double-zincate method of claim 12, wherein said oxidizing agent has a concentration of at least 1 g/L.

14. A method of forming a metal plating film on a material that is aluminum or an aluminum alloy, comprising:
an etching step of etching said material by an etching solution containing copper ions,
a residue removal step of removing etching residues from said material going through said etching step using a stripping solution capable of dissolving copper,
a first zinc immersion coating step of immersing said material in a zinc immersion coating solution at least containing a zinc compound, an alkali hydroxide, an iron salt, a chelating agent for complexation of iron ions, and a zinc immersion coating inhibitor, said zinc immersion coating inhibitor being at least one out of the group consisting of a polymer of a secondary amine, a polymer of a tertiary amine, and a polymer of a quaternary amine, or a copolymer containing the same,
a step of immersing said material in an aqueous solution of nitric acid,
a second zinc immersion coating step of immersing said material in a zinc immersion coating solution at least containing a zinc compound, an alkali hydroxide, an iron salt, a chelating agent for complexation of iron ions, and a zinc immersion coating inhibitor, said zinc immersion coating inhibitor being at least one out of the group consisting of a primary amine, a secondary amine, and a tertiary amine, and
a plating step of forming a metal plating film on said material by plating after said second zinc immersion coating step.

15. The method of forming a metal plating film according to claim 14, wherein said zinc immersion coating solution used in said first zinc immersion coating step contains said zinc immersion coating inhibitor in an amount ranging from 0.05 to 50 g/L, and said zinc immersion coating solution used in said second zinc immersion coating step contains said zinc immersion coating inhibitor in an amount ranging from 0.01 to 1 mol/L.

16. The method of forming a metal plating film according to claim 14, wherein in said plating step, said metal plating film is formed by at least one plating method out of electroless plating, displacement plating, displacement/reduction plating, and electroplating, wherein for said displacement/reduction plating, a plurality of baths are used to carry out displacement plating and reduction plating in order, or a single bath is used to carry out displacement plating and reduction plating in parallel.

17. A semiconductor device including an aluminum or aluminum alloy electrode having a metal plating film thereon, wherein:
said metal plating film has been formed by etching said electrode by an etching solution containing copper ions, then removing etching residues from said electrode using a stripping solution capable of dissolving copper, then immersing said electrode in a first zinc immersion coating solution, then immersing said electrode in an aqueous solution of nitric acid, then immersing said electrode in a second zinc immersion coating solution, and then applying plating to said electrode, wherein said first zinc immersion coating solution at least contains a zinc compound, an alkali hydroxide, an iron salt, a chelating agent for complexation of iron ions, and a zinc immersion coating inhibitor, wherein said zinc immersion coating inhibitor is at least one out of the group consisting of a polymer of a secondary amine, a polymer of a tertiary amine, and a polymer of a quaternary amine, or a copolymer containing the same, and said second zinc immersion coating solution at least contains a zinc compound, an alkali hydroxide, an iron salt, a chelating agent for complexation of iron ions, and a zinc immersion coating inhibitor, wherein said zinc immersion coating inhibitor is at least one out of the group consisting of a primary amine, a secondary amine, and a tertiary amine.

18. The semiconductor device of claim 17, wherein said first zinc immersion coating solution contains said zinc immersion coating inhibitor in an amount ranging from 0.05 to 50 g/L, and said second zinc immersion coating solution contains said zinc immersion coating inhibitor in an amount ranging from 0.01 to 1 mol/L.

19. The semiconductor device of claim 17, wherein said metal plating film has been formed by application to said electrode of at least one plating method out of electroless plating, displacement plating,
displacement/reduction plating, and electroplating, wherein for said displacement/reduction plating, a plurality of baths are used to carry out displacement plating and reduction plating in order, or a single bath is used to carry out displacement plating and reduction plating in parallel.

20. The semiconductor device of claim 17, wherein said metal plating film has a nickel plating film and a gold plating film laminated in order from said electrode or a nickel plating film, a palladium plating film and a gold plating film laminated in order from said electrode, said gold plating film having been formed by displacement/reduction plating wherein for said displacement/reduction plating, a plurality of baths are used to carry out displacement plating and reduction plating in order, or a single bath is used to carry out displacement plating and reduction plating in parallel.
